(19) United States
(12) Patent Application Publication
(10) Pub. No.: US 2017/0370997 A1
(43) Pub. Date: Dec. 28, 2017

(54) METHOD FOR ESTIMATING CHARACTERISTIC PHYSICAL QUANTITIES OF AN ELECTRIC BATTERY

(71) Applicant: RENAULT S.A.S., Boulogne-Billancourt (FR)

(72) Inventor: Sylvain LEIRENS, Gif Sur Yvette (FR)

(73) Assignee: RENAULT s.a.s., Boulogne-Billancourt (FR)

(21) Appl. No.: 15/538,549

(22) PCT Filed: Dec. 16, 2015
(86) PCT No.: PCT/FR2015/053557

§ 371 Date: Jul. 13, 2017

(30) Foreign Application Priority Data
Dec. 22, 2014 (FR) 1463162

(51) Int. Cl. G01R 31/36

(52) U.S. Cl. CPC G01R 31/3651; G01R 31/3662

(57) ABSTRACT

A method estimates physical quantities that are characteristic of an electric battery. The method includes acquiring values of a voltage across terminals of the electric battery and values of an intensity of a current output by the electric battery, over a determined duration. The method also includes obtaining the values of the physical quantities by solving a system of linear equations modeling an electrical behavior of the electric battery, unknowns of which are mathematically linked to the physical quantities and coefficients of which are obtained beforehand, by integrating voltage functions or intensity functions over the determined duration.

### TECHNICAL FIELD OF THE INVENTION

The present invention relates in general to the monitoring of an electric battery.

It relates more particularly to a method for estimating physical quantities that are characteristic of an electric battery, including steps:
a)of acquiring values of the voltage across the terminals of the battery and values of the intensity of the current output by the battery, over a determined duration and
b)of calculating said quantities, which include, for example, the internal resistance of the battery, as a function of the voltage and the current intensity that were acquired in step a).

The invention applies, particularly advantageously, to automotive vehicles fitted with an electric motor supplied with power by an electric battery referred to as a drive battery.

### TECHNOLOGICAL BACKGROUND

As is well known, the electric power that an electric battery is able to provide decreases over the course of a discharge cycle.

It is also well known that the maximum charge capacity of a battery decreases over the course of the life of this battery.

In order to predict when it is necessary to recharge the battery in order to make best use of the stored electric power, it is sought to determine the values of physical quantities that are characteristic of this battery, for example that of its internal resistance. The values of these quantities are in particular used to estimate the state of charge and state of health of the battery.

The values of such physical quantities are in general deduced from measurements of the voltage across the terminals of the battery, of the intensity of the current output thereby, and potentially of the temperature of the battery. For an on-board battery, for example in an automotive vehicle, these measurements are most often noisy, which can have a negative effect on the accuracy of the estimate of said quantities.

Document WO2007100189 describes a method for estimating such quantities allowing the influence of this measurement noise to be decreased through the use of a Kalman filter. It takes the form of an iterative method in which, at each time interval:
an assumed state of the battery is calculated as a function of the state of the battery measured in the preceding time interval, and as a function of the measured intensity;
the voltage calculated on the basis of the assumed state of the battery is compared with the measured voltage, which provides an error;
the assumed state of the battery is corrected according to the calculated error.

This estimation method has two main drawbacks. On the one hand, it is an iterative method in which the aforementioned steps are repeated in a loop multiple times until the calculated error is small. The convergence of this iterative calculation toward an accurate result may take a long time, and in any case is not always guaranteed. On the other hand, it is a method referred to as a discrete time method that requires the measured signals to be sampled regularly over time. This is not always the case in practice, which risks negatively affecting the accuracy of the estimate of the physical quantities that are characteristic of the battery.

### SUBJECT OF THE INVENTION

In order to overcome the aforementioned drawbacks of the prior art, the present invention proposes a method for estimating physical quantities that are characteristic of an electric battery, such as defined in the introduction, in which the values of said physical quantities are obtained by solving a system of linear equations modeling the electrical behavior of the electric battery:
the unknowns of which are mathematically linked to said physical quantities;
and the coefficients of which are obtained beforehand, by integrating voltage functions or intensity functions over the determined duration.

This estimation method is non-iterative and is thus intrinsically exempt from convergence problems.

Since the coefficients of said system of linear equations are obtained by integration over a determined duration, the integration calculation does not require the sampling of the voltage and of the intensity to be regular over time. This method can therefore be used without loss of accuracy even when the voltage or the intensity is not sampled regularly over time.

Lastly, this step of integrating the measured signals acts as a low-pass filter, thereby making the method robust with respect to measurement noise, which is generally located at high frequencies.

Other advantageous and non-limiting features of such an estimation method in accordance with the invention are the following:
said system of linear equations is obtained by transforming, using Laplace transform calculations, a differential equation that models the electrical behavior of the battery and which links the voltage, the intensity and said physical quantities;
said coefficients are obtained by calculating successive integrals of voltage functions or intensity functions over a determined duration;
said calculation of successive integrals over the determined duration may be performed by applying the Cauchy formula:

$${\int }_{0}^{t} {\int }_{0}^{{τ}_{1}} … {\int }_{0}^{{τ}_{n - 1}} {τ}_{n}^{m} f ( {τ}_{n} ) d {τ}_{n} d {τ}_{n - 1} … d {τ}_{1} = \frac{1}{( n - 1 ) !} {\int }_{0}^{t} {( t - τ )}^{n - 1} {τ}^{m} f ( τ ) d τ$$

where t represents time, m and n are two integers and f(t) is a function of time, here equal to the voltage or to the intensity; using the Cauchy formula allows a quicker and more accurate numerical evaluation than a direct numerical calculation of such successive integrals;
said coefficients of said system of linear equations are obtained by calculating inverse Laplace transforms of quantities equal to

$$\frac{1}{{s}^{n}} \frac{{d}^{m} \tilde{f} ( s )}{{ds}^{m}}$$

where \tilde{f}(s) represents the Laplace transform of the function f(t), f(t) represents a function of time, equal to the voltage or to the intensity, s represents the Laplace variable, m represents an integer and n represents a real number that is not necessarily an integer;
said inverse Laplace transform calculations are performed by applying a generalized Cauchy formula when the number n is not an integer:

$${TL}^{- 1} ( \frac{1}{{s}^{n}} \frac{{d}^{m} \tilde{f} ( s )}{{ds}^{m}} ) = \frac{{( - 1 )}^{m}}{Γ ( n )} {\int }_{0}^{t} {( t - τ )}^{n - 1} {τ}^{m} f ( τ ) d τ$$

where Γ(n) is the Euler gamma function defined by:

Γ(n)=∫₀^{∞}xⁿ⁻¹e^{-x}dx

Using the generalized Cauchy formula allows the quantities that are characteristic of the battery to be estimated even when the differential equation that models its electrical behavior is a differential equation of non-integer order.

The invention additionally proposes a method in which the values of said physical quantities that are characteristic of the battery are obtained:
either by inverting said system of linear equations in order to obtain a formal expression for each quantity.
or by numerically solving said system of linear equations.

It is also possible for said differential equation to be the following:

$$U - {U}_{OC} + {R}_{1} {C}_{1} \frac{dU}{dt} = ( {R}_{0} + {R}_{1} ) I + {R}_{0} {R}_{1} {C}_{1} \frac{dI}{dt}$$

where t represents time, Uoc represents the open circuit voltage of the electric battery, R₀ represents the internal resistance of the electric battery and the pair (R₁, C₁) constitutes the diffusion model of the battery, R₀, R₁ and C₁ being the physical quantities to be estimated.

### DETAILED DESCRIPTION OF ONE EXEMPLARY EMBODIMENT

The following description with reference to the appended drawings, given by way of non-limiting examples, will allow it to be clearly understood of what the invention consists and how it can be achieved.

In the appended drawings:

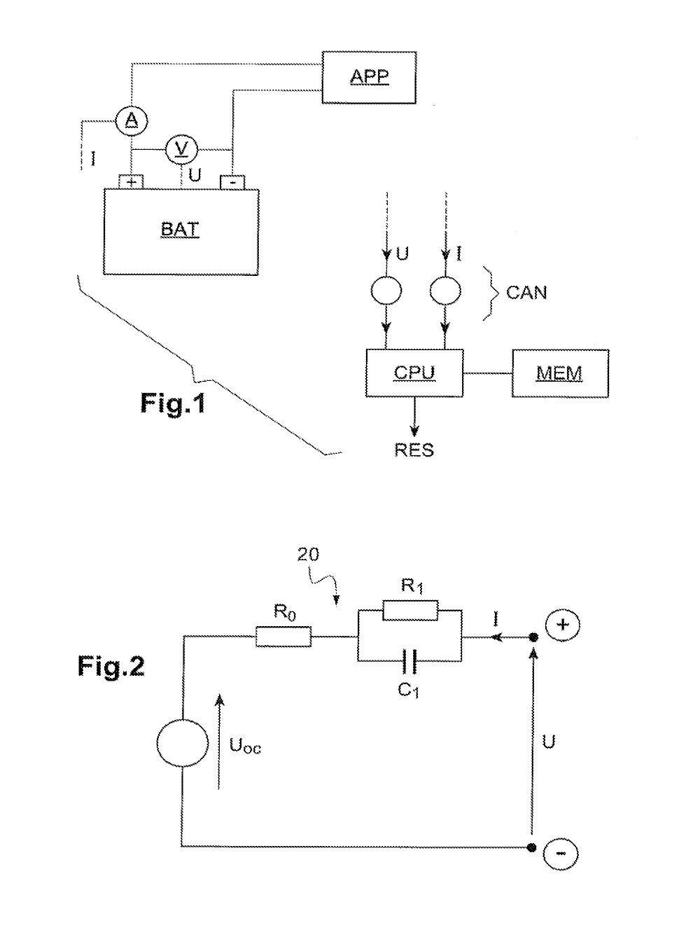

FIG. 1 is a schematic view of an electric battery, of the sensors and of a calculation unit which are suitable for implementing a method in accordance with the invention, allowing physical quantities of this battery to be estimated;

FIG. 2 is a circuit diagram corresponding to an exemplary model of the electric battery of FIG. 1.

FIG. 1 shows an electric battery BAT that supplies electric current to an item of electrical equipment APP. The voltage U across the terminals of this electric battery BAT is measured by a voltage sensor V. The intensity I of the electric current output by the electric battery BAT is measured by a current sensor A. Analog-to-digital converters allow the values of this voltage U and of this intensity I to be sampled and digitized. The data thus obtained are used by a processor CPU to estimate, according to the method that is the subject of the present invention, the values RES of physical quantities that are characteristic of the electric battery BAT. The memorization module MEM is used in particular to store information required for this calculation.

FIG. 2 illustrates a circuit diagram corresponding to an exemplary model of the electric battery of FIG. 1. As shown in this FIG. 2, the electric battery BAT is here modeled by an electric circuit comprising, in series, an ideal voltage source U_{OC}, a resistor R₀, and a pair comprising a resistor R₁ and a capacitor C₁ connected in parallel to one another. In this context, the voltage source models the open circuit voltage, the resistor R₀ models the internal resistance of the battery, and the resistor R₁-capacitor C₁ pair models the internal diffusion phenomena of the battery.

In the context of this model, the physical quantities that it is sought to estimate are the internal resistance R₀ of the battery and the pair (R₁, C₁). The open circuit voltage U_{OC} is for its part assumed to be known. The differential equation corresponding to this electric circuit 20 is:

$$u + {R}_{1} {C}_{1} \frac{du}{dt} = ( {R}_{0} + {R}_{1} ) I + {R}_{0} {R}_{1} {C}_{1} \frac{dI}{dt} \qquad ( F 4 )$$

where t represents time and where the notation u=U−U_{OC} is used. The differential equation F4 may take the equivalent form F5:

$$u + {a}_{1} \frac{du}{dt} = {b}_{0} I + {b}_{1} \frac{dI}{dt} \qquad ( F 5 )$$

In order to estimate the physical quantities R₀, R₁ and C₁, the processor CPU starts by calculating the value of the three parameters b₀, b₁ and a₁ on the basis of the recording, over a duration T, of the values of the voltage U and of the current I, according to a calculation described below.

Once the values of b₀, b₁ and a₁ are known, the processor CPU calculates the value of the physical quantities R₀, R₁ and C₁ using the relationships:

R₀=b₁/a₁, R₁=b₀−b₁/a₁ and C₁=a₁²/(a₁b₀−b₁).

The values of these parameters b₀, b₁ and a₁ are calculated by the processor on the basis of the system of three linear equations F6 of which the three unknowns are the parameters b₀, b₁ and a₁:

$$\begin{matrix}[ \begin{matrix}{m}_{11} & {m}_{12} & {m}_{13} \\ {m}_{21} & {m}_{22} & {m}_{23} \\ {m}_{31} & {m}_{32} & {m}_{33}\end{matrix} ] [ \begin{matrix}{b}_{0} \\ {b}_{1} \\ {a}_{1}\end{matrix} ] = [ \begin{matrix}{γ}_{1} \\ {γ}_{2} \\ {γ}_{3}\end{matrix} ] \\ where \text{:} & ( F6 ) \\ \begin{matrix}{m}_{11} = - {\int }_{ }^{( 2 )} t 1 & {m}_{12} = {\int }_{ }^{( 2 )} 1 - \int t 1 & {m}_{13} = - {\int }_{ }^{( 2 )} u + \int tu \\ {m}_{21} = {\int }_{ }^{( 2 )} {t}^{2} 1 & {m}_{22} = - 2 {\int }_{ }^{( 2 )} t 1 + \int {t }^{2} 1 & {m}_{23} = 2 {\int }_{ }^{( 2 )} tu - \int {t}^{2} u \\ {m}_{31} = - {\int }_{ }^{( 2 )} {t}^{3} 1 & {m}_{32} = 3 {\int }_{ }^{( 2 )} {t}^{2} 1 - \int {t}^{3} 1 & {m}_{33} = - 3 {\int }_{ }^{( 2 )} {t}^{2} u + \int {t}^{3} u \\ and \text{:} {γ}_{1} = - {\int }_{ }^{( 2 )} tu & {γ}_{2} = {\int }_{ }^{( 2 )} {t}^{2} u & {γ}_{3} = - {\int }_{ }^{( 2 )} {t}^{3} u\end{matrix} \} & ( F7 )\end{matrix}$$

In the above expressions, in order to simplify the text, the following notations have been used for the successive integrals:

∫₀^{T}∫₀^{τ}^{₁} . . . ∫₀^{τ}^{_{n−1}} τₙ^{m}f(τₙ) dτₙ dτₙ₋₁ . . . dτ₁ is denoted: ∫⁽ⁿ⁾t^{m}f

For example:

∫₀^{T}f(τ) dτ is denoted: ∫f

and ∫₀^{T}∫₀^{τ}f(σ) dσ dτ is denoted: ∫⁽²⁾f

where f is equal to u or I.

In order to obtain the values b₀, b₁ and a₁ from the system F6, the processor CPU either numerically solves this system or performs a direct calculation using the general solution F8 for such a system:

$$[ \begin{matrix}{b}_{0} \\ {b}_{1} \\ {a}_{1}\end{matrix} ] = \frac{1}{det ( M )} [ \begin{matrix}{m}_{22} {m}_{33} - {m}_{32} {m}_{23} & {m}_{32} {m}_{13} - {m}_{12} {m}_{33} & {m}_{21} {m}_{23} - {m}_{22} {m}_{13} \\ {m}_{31} {m}_{23} - {m}_{21} {m}_{33} & {m}_{11} {m}_{33} - {m}_{31} {m}_{13} & {m}_{21} {m}_{13} - {m}_{11} {m}_{23} \\ {m}_{21} {m}_{32} - {m}_{31} {m}_{22} & {m}_{31} {m}_{12} - {m}_{11} {m}_{32} & {m}_{11} {m}_{22} - {m}_{21} {m}_{12}\end{matrix} ] [ \begin{matrix}{γ}_{1} \\ {γ}_{2} \\ {γ}_{3}\end{matrix} ] \qquad ( F8 )$$

where det (M)=m₁₁m₂₂m₃₃−m₁₁im₂₃m₃₂−m₁₂m₂₁m₃₃+m₁₂m₂₃m₃₁+m₁₃m₂₁m₃₂−m₁₃m₂₂m₃₁.

In the case of a numerical solution for the system F6, the calculation may for example be performed by means of the Gauss-Jordan method, or else using the well-known technique consisting in factorizing the matrix M into two triangular matrices, one upper and the other lower (referred to as LU (lower-upper) decomposition).

Regardless of whether the calculation of the values b₀, b₁ and a₁ is performed by numerically solving the system F6 or by a direct calculation using its general solution F8, it requires the numerical calculation of the coefficients m₁₁ to m₃₃ and γ₁, γ₂, γ₃. As shown by their expressions F7, the calculation of these coefficients corresponds to an integration calculation, over the duration T, of voltage U or current I functions. This integration may for example be performed like a numerical calculation of cumulative discrete sums. By way of illustration, a numerical evaluation of the quantity ∫tI may be obtained by calculating the sum:

Σⱼ₌₁^{k}[Σ_{q=1}^{j}Tₑ(q)],I(j),T(j) (F9)

where Tₑ(j) is the duration separating the samples j and j+1, I(j) is the value of the intensity corresponding to the sample number j, and k+1 is the total number of samples acquired over the duration T. The total duration of acquisition T is in this case equal to the sum Σⱼ₌₁^{k}Tₑ(j).

This total duration T, during which the voltage U and the intensity I are acquired, is an important adjustment parameter in this estimation method. The choice thereof may be guided by potential prior knowledge of the predominant dynamics of the battery, in particular of its longest characteristic variation times. A few tests also allow, in general, a value of T to be determined which leads to an accurate estimate of the parameters of the battery.

In another variant, the successive integrals of the formulas F7 are calculated using the Cauchy formula F1:

$${\int }_{0}^{t} {\int }_{0}^{{τ}_{1}} … {\int }_{0}^{{τ}_{n - 1}} {τ}_{n}^{m} f ( {τ}_{n} ) d {τ}_{n} d {τ}_{n - 1} … d {τ}_{1} = \frac{1}{( n - 1 ) !} {\int }_{0}^{t} {( t - τ )}^{n - 1} {τ}^{m} f ( τ ) d τ \qquad ( F1 )$$

I.e. for example:

∫₀^{T}∫₀^{τ}f(σ) dσ dτ=∫₀^{T}(T−τ)f(τ)dτ

One of the advantages of this transformation is that the right-hand term of equation F1 lends itself to quicker numerical calculation than that on the left, and with less accumulation of calculation errors.

Calculating the physical quantities of the battery, whether R₀, R₁ or C₁, makes it possible to track the variation in the charge and in the behavior of the electric battery BAT. These three physical quantities thus in particular make it possible to obtain monitoring parameters of the electric battery BAT, such as the state of charge SOC of the battery and the state of health SOH of the battery.

As shown by the description above, this method for estimating the value of the physical quantities R₀, R₁ and C₁ has multiple advantages.

First of all, it is direct and deterministic: the quantities R₀, R1 and C₁ may be expressed explicitly as a function of the values of the voltage U and of the intensity I recorded over a duration T. This estimation method is therefore exempt from problems of convergence of the result, unlike certain iterative estimation methods.

In addition, in order to optimize the accuracy of this estimation method in practice, just one parameter must be adjusted; this parameter is the overall duration of acquisition T. This adjustment is simpler than that of the methods using state observers (for example using a Kalman filter) for which it would have been necessary here to adjust the initial values of three parameters (one per quantity to be estimated) in order to provide a result with a high level of accuracy.

This method is also intrinsically robust with respect to measurement noise, which is in general located at high frequencies. Specifically, the use of integrals over time (see formulas F7, or formula F1) performs filtering of low-pass type on the measured signal U(t) or I(t).

Next, it requires little in the way of calculation means, since, in order to estimate the three unknown quantities, it is necessary either to calculate three simple expressions (see formula F8) or to solve a system of three equations with three unknowns (system F6), the size of which is therefore decreased as far as possible.

Lastly, it is compatible with temporally irregular data sampling, i.e. with sampling for which the duration separating two samples is not constant. The coefficients m₁₁ to m₃₃ and γ₁, γ₂, γ₃ by numerical integration may indeed be calculated even in this case. By way of example, in formula (F9), the duration Tₑ(j) separating the samples j and j+1 may vary from one sample to the other.

In the method described above, the formulas used in practice by the processor in order to estimate the physical quantities of the battery are primarily formulas F6 and F7.

The implementation of the invention by the processor CPU having been described in detail, it is now possible to explain how, on the basis of equation F5, these formulas F6 and F7 have been obtained.

First of all, the Laplace transform TL of equation F5 is calculated in order to obtain:

ũ+a₁(sũ−u(t=0))=b₀Ĩ+b₁(sĨ−I(t=0)) (F10)

where the Laplace variable is denoted by s, ũ is the Laplace transform of u, and i is the Laplace transform of I.

Equation F10 is then derived once, twice and three times, respectively, with respect to s, then divided by s², in order to obtain the system of three equations F11:

$$( F 11 ) \\ \begin{matrix}\frac{1}{{s}^{2}} \frac{d \tilde{u}}{ds} + {a}_{1} ( \frac{1}{{s}^{2}} \tilde{u} + \frac{1}{s} \frac{d \tilde{u}}{ds} ) = {b}_{0} \frac{1}{{s}^{2}} \frac{d \tilde{l}}{ds} + {b}_{1} ( \frac{1}{{s}^{2}} \tilde{l} + \frac{1}{s} \frac{d \tilde{l}}{ds} ) \\ \frac{1}{{s}^{2}} \frac{{d}^{2} \tilde{u}}{{ds}^{2}} + {a}_{1} ( 2 \frac{1}{{s}^{2}} \frac{d \tilde{u}}{ds} + \frac{1}{s} \frac{{d}^{2} \tilde{u}}{{ds}^{2}} ) = {b}_{0} \frac{1}{{s}^{2}} \frac{{d}^{2} \tilde{l}}{{ds}^{2}} + {b}_{1} ( 2 \frac{1}{{s}^{2}} \frac{d \tilde{l}}{ds} + \frac{1}{s} \frac{{d}^{2} \tilde{l}}{{ds}^{2}} ) \\ \frac{1}{{s}^{2}} \frac{{d}^{3} \tilde{u}}{{ds}^{3}} + {a}_{1} ( 3 \frac{1}{{s}^{2}} \frac{{d}^{2} \tilde{u}}{{ds}^{2}} + \frac{1}{s} \frac{{d}^{3} \tilde{u}}{{ds}^{3}} ) = {b}_{0} \frac{1}{{s}^{2}} \frac{{d}^{3} \tilde{l}}{{ds}^{3}} + {b}_{1} ( 3 \frac{1}{{s}^{2}} \frac{{d}^{2} \tilde{l}}{{ds}^{2}} + \frac{1}{s} \frac{{d}^{3} \tilde{l}}{{ds}^{3}}\end{matrix} \}$$

Next, the inverse Laplace transform of system F11 is calculated. Given the expression of system F11, its inverse Laplace transform comprises quantities such as:

$${TL}^{- 1} ( \frac{1}{{s}^{n}} \frac{{d}^{m} \tilde{f} ( s )}{{ds}^{m}} )$$

where f(t) is equal to the voltage U(t) or to the intensity I(t). Since m and n are integers in this instance, these Laplace transforms are expressed as:

$${TL}^{- 1} ( \frac{1}{{s}^{n}} {\tilde{f}}^{( m )} ( s ) ) = {( - 1 )}^{m} {\int }_{0}^{t} {\int }_{0}^{{τ}_{1}} … {\int }_{0}^{{τ}_{n - 1}} {τ}_{n}^{m} f ( {τ}_{n} ) d {τ}_{n} d {τ}_{n - 1} … d {τ}_{1} \qquad ( F12 )$$

Calculating the inverse Laplace transform of system F11 thus finally leads to formulas F6 and F7, which in practice are of use in numerically estimating the characteristic quantities of the battery.

The estimation method that is the subject of the present invention is described above on the basis of an exemplary model of the electric battery BAT which is represented in FIG. 2 and which corresponds to differential equation F4.

It is more generally applicable to any electric battery the electrical behavior of which can be modeled by a differential equation ED linking the voltage U, the current I and the physical quantities to be estimated. in order to apply this method to such a battery model, it is necessary to transform the corresponding differential equation ED beforehand into a system of linear equations such as F6, by means of formal Laplace transform calculations similar to those which have been described above in order to set up the system of equations F6 on the basis of equation F4.

This estimation method is particularly applicable to the case of differential equations ED of non-integer order, as shown by the example described below.

The physical battery model corresponding to the circuit diagram of FIG. 2, presented above, may be improved by considering the intensity i_{C}_{₁} that passes through the capacitor C₁ to be linked to the voltage U_{C}_{₁} across its terminals by the relationship:

$${i}_{{C}_{1}} = {C}_{1} \frac{{d}^{α} {U}_{{C}_{1}}}{{dt}^{α}} \qquad ( F13 )$$

where α is a real (not necessarily integer) constant, in general between 0 and 1. Such a capacitive element is referred to as a constant phase element. The differential equation that describes the variation in the voltage U(t) is then:

$$U - {U}_{OC} + {a}_{1} \frac{{d}^{α} U}{{dt}^{α}} = {b}_{0} I + {b}_{1} \frac{{d}^{α} I}{{dt}^{α}} \qquad ( F14 )$$

This differential equation is transformed as above in order to obtain a system of three linear equations the unknowns of which are the physical parameters b₀, b₁ and a₁.

To do this, the Laplace transform of equation F14 is calculated, then it is multiplied by s^{1-α} in order to obtain:

s^{1-α}ũ+a₁(sũ−u(t=0))=s^{1-α}b₀Ĩ+b₁(sĨ−I(t=0)) (F15)

Next, equation F15 is derived once, twice and three times, respectively, with respect to s, then divided by s2 in order to obtain a system of three equations F16. The first equation of this system is:

$$( 1 - α ) \frac{\tilde{u}}{{s}^{2 + o}} + \frac{1}{{s}^{1 + u}} \frac{d \tilde{u}}{ds} + {a}_{1} ( \frac{\tilde{u}}{{s}^{2}} + \frac{1}{s} \frac{d \tilde{u}}{ds} ) = ( 1 - α ) \frac{{b}_{0}}{{s}^{2 + α}} \tilde{l} + \frac{{b}_{0}}{{s}^{1 + α}} \frac{d \tilde{l}}{ds} + {b}_{1} ( \frac{\tilde{l}}{{s}^{2}} + \frac{1}{s} \frac{d \tilde{l}}{ds} ) \qquad ( F16a )$$

The two other equations of this system, which can be obtained directly from equation F15, are not described in detail here.

As above, the inverse Laplace transform of system F16 is calculated next, finally resulting in a system of linear equations similar to system F6, which is used by the processor in order to estimate the value of the physical parameters b₀, b₁ and a₁.

Given the form of the system of equations F16, its inverse Laplace transform comprises quantities such as:

$${TL}^{- 1} ( \frac{1}{{s}^{n}} \frac{{d}^{m} \tilde{f} ( s )}{{ds}^{m}} )$$

where f(t) is equal to the voltage U(t) or to the intensity I(t). Here, n is a real number which is not necessarily an integer (for this exemplary embodiment, it may for example be equal to 2+α). In order to calculate such inverse Laplace transforms, a generalized Cauchy formula F2 is then used:

$${TL}^{- 1} ( \frac{1}{{s}^{n}} {\tilde{f}}^{( m )} ( s ) ) = \frac{{( - 1 )}^{m}}{Γ ( n )} {\int }_{0}^{t} {( t - τ )}^{n - 1} {τ}^{m} f ( τ ) d τ \qquad ( F2 )$$

where Γ(n) is the Euler gamma function defined by:

Γ(n)=∫₀^{∞}xⁿ⁻¹e^{-x}dx (F3)

The function Γ(n) is easy to calculate numerically, since the integral converges rapidly in practice.

The method described above applies particularly advantageously to the estimation of physical quantities that are characteristic of an on-board electric battery, for example in an electrically driven automotive vehicle, or in a computer supplied with power by such a battery.

1-9. (canceled)

10. A method for estimating physical quantities that are characteristic of an electric battery, comprising:
acquiring values of a voltage across terminals of the electric battery and values of an intensity of a current output by the electric battery, over a determined duration,
obtaining the values of said physical quantities by solving a system of linear equations modeling an electrical behavior of the electric battery:
unknowns of which are mathematically linked to said physical quantities; and
coefficients of which are obtained beforehand, by integrating voltage ftmctions or intensity functions over the determined duration.

11. The method as claimed in claim 10, in which said system of linear equations is obtained by transforming, using Laplace transform calculations, a differential equation that models the electrical behavior of the electric battery and which links the voltage, the intensity, and said physical quantities.

12. The method as claimed in claim 10, in which said coefficients are obtained by calculating successive integrals of voltage functions or intensity functions over the determined duration.

13. The method as claimed in claim 12, in which said calculation of successive integrals over the deteimined duration is performed by applying the Cauchy formula:
$${\int }_{0}^{t} {\int }_{0}^{{τ}_{1}} … {\int }_{0}^{{τ}_{n - 1}} {τ}_{n}^{m} f ( {τ}_{n} ) d {τ}_{n} d {τ}_{n - 1} … d {τ}_{1} = \frac{1}{( n - 1 ) !} {\int }_{0}^{t} {( t - τ )}^{n - 1} {τ}^{m} f ( τ ) d τ$$
where t represents time, m and n are two integers and f(t) is a function of time, here equal to the voltage or to the intensity.

14. The method as claimed in claim 11, in which said coefficients are obtained by calculating inverse Laplace transforms of quantities equal to
$$\frac{1}{{s}^{n}} \frac{{d}^{m} \tilde{f} ( s )}{{ds}^{m}}$$
where \tilde{f}(s) represents the Laplace transform of the function f(t), f(t) represents a function of time, equal to the voltage or to the intensity, s represents the Laplace variable, m represents an integer and n represents a real number that is not necessarily an integer.

15. The method as claimed in claim 14, in which said inverse Laplace transform calculations are performed by applying a generalized Cauchy formula:
$${TL}^{- 1} ( \frac{1}{{s}^{n}} \frac{{d}^{m} \tilde{f} ( s )}{{ds}^{m}} ) = \frac{{( - 1 )}^{m}}{Γ ( n )} {\int }_{0}^{t} {( t - τ )}^{n - 1} {τ}^{m} f ( τ ) d τ$$
where Γ(n) is the Euler gamma function defined by:
Γ(n)=∫₀^{∞}xⁿ⁻¹e^{-x}dx
where t represents time, m and n are two integers and f(t) is a function of time.

16. The method as claimed in claim 10, in which the values of the physical quantities are obtained by inverting said system of linear equations in order to obtain a formal expression for each quantity.

17. The method as claimed claim 10, in which the values of the physical quantities are obtained by numerically solving said system of linear equations.

18. The method as claimed in claim 11, in which said differential equation is the following:
$$U - {U}_{OC} + {R}_{1} {C}_{1} \frac{dU}{dt} = ( {R}_{0} + {R}_{1} ) I + {R}_{0} {R}_{1} {C}_{1} \frac{dI}{dt} ,$$
where t represents time, Uoc represents an open circuit voltage of the electric battery, R₀ represents the internal resistance of the battery and the pair (R₁, C₁) constitutes the diffusion model of the battery, R₀, R₁ and C₁ being the physical quantities to be estimated.
